(19) United States
(12) Patent Application Publication
(10) Pub. No.: US 2010/0314746 A1
(43) Pub. Date: Dec. 16, 2010

(54) SEMICONDUCTOR PACKAGE AND MANUFACTURING METHOD THEREOF

(76) Inventors: Chueh-An Hsieh, Kaohsiung City (TW); Min-Lung Huang, Kaohsiung City (TW)

Correspondence Address: COOLEY LLP;ATTN: Patent Group, Suite 1100, 777 - 6th Street, NW, WASHINGTON, DC, 20001, US

(21) Appl. No.: 12/580,869

(22) Filed: Oct. 16, 2009

(30) Foreign Application Priority Data
Jun. 11, 2009 (TW) 98119595

(51) Int. Cl. H01L 23/48; H01L 21/50

(52) U.S. Cl. 257/692; 438/113; 438/124; 257/E23.01; 257/E21.499

(57) ABSTRACT

A semiconductor package and a manufacturing method thereof are provided. A carrier having an adhesion layer is provided. A plurality of chips are disposed on the adhesion layer, wherein an active surface of each chip faces the adhesion layer. A molding compound is formed for encapsulating the chips to form a chip-redistribution encapsulant having a first surface and a second surface, wherein the first surface has a chip area and a peripheral area. The carrier and the adhesion layer are removed, so that the chip-redistribution encapsulant exposes the active surface of each chip. A plurality of solder balls are uniformly formed in the chip area and the peripheral area. The second surface of the chip-redistribution encapsulant is grinded to reduce the thickness of the chip-redistribution encapsulant, wherein the solder balls provide the chip-redistribution encapsulant with a uniform support. The chip-redistribution encapsulant is sawn to form a plurality of packages.

This application claims the benefit of Taiwan application Serial No. 98119595, filed Jun. 11, 2009, the subject matter of which is incorporated herein by reference.

### BACKGROUND OF THE INVENTION

1. Field of the Invention

The invention relates in general to a semiconductor package and a manufacturing process thereof, and more particularly to a chip-redistribution encapsulant level package and a packaging process thereof.

2. Description of the Related Art

In recent years, electronic devices are widely used in people's everyday life, and various miniature and multi-function electronic products are provided to meet the market demand. Currently, there are various semiconductor packages being provided. However, in most package processes, the crystalline grains disposed on the chip-redistribution encapsulant are divided into individual crystalline grain first and then each crystalline grain is packaged and tested.

The processing target is a single die according to conventional package technology, but is an entire chip-redistribution encapsulant in a chip-redistribution encapsulant level package. Compared with the conventional single die package, the chip-redistribution encapsulant level package packages the crystalline grains disposed on the chip-redistribution encapsulant before the crystalline grains are separated. Thus, the back-end process of the chip package is simplified, and the time and the cost for manufacturing package are reduced. That is, after the front-end process applied to the elements and circuits on the surface of the chip-redistribution encapsulant is completed, the back-end process is directly applied to the entire chip-redistribution encapsulant, and the step of sawing the chip-redistribution encapsulant is performed to form a plurality of chips package. Thus, the chip-redistribution encapsulant level package has become a mainstream semiconductor package.

The semiconductor chip is directed towards the trend of thinness and miniaturization. In terms of the current chip-redistribution encapsulant level package technology, when the grinding process is applied to reduce the height of the chip-redistribution encapsulant of the semiconductor package, fragmentation may occur to the chip, largely deteriorating the conformity rate of the package and increasing the manufacturing cost. Referring to FIG. 1, fragmentation occurring to the chip-redistribution encapsulant is shown. The chip-redistribution encapsulant includes a chip area 10 and the peripheral area 20. A plurality of chips and the alignment marking element (G) 120 are disposed in the chip area 10. Of the chips, fragmentation occurs to almost all chips 102 near the peripheral area 20 and all chips 104 near the alignment marking element (G) 120 except the normal chip 100.

FIG. 2A shows the chip-redistribution encapsulant receiving stress during the grinding process. For thinner packages, to avoid warpage occurring during the process of implanting the balls, normally, the ball implanting process is performed before the grinding process. Before the grinding process, a film of grinding tape 262 is adhered on the surface of the chip-redistribution encapsulant to avoid the surface of the chip-redistribution encapsulant directly receiving stress. However, when the grinding tool 260 grinds the molding compound 240 from the backside of the chip-redistribution encapsulant, the stress applied on the entire chip-redistribution encapsulant is uneven as the solder balls 250 are already formed on the chips 2301, 2302, and 2303. As indicated in FIG. 2A, on the part of the chip-redistribution encapsulant, the stress P1 received in the peripheral area A1 and the stresses P3 and P4 received directly under the alignment marking element 220 in the chip area A2 are greater than the stresses P2′ and P5′ received in other part of the chip-redistribution encapsulant. Thus, the stresses received on the two sides of the chip 2301 near the peripheral area A1 are not the same (P1>P2). Moreover, the stresses received on the two sides of the chips 2302 and 2303 near the alignment marking element 220 are not the same either (P3>P2 and P4>P5). Therefore, fragmentation occurs to the part of the chip 2301 near the peripheral area A1 and the part of the chips 2302 and 2303 near the alignment marking element 220. Such fragmentation cannot be automatically detected by machine and each chip must be manually examined by using optical microscopy, which incurs a large amount of labor cost.

### SUMMARY OF THE INVENTION

The invention is directed to a semiconductor package and a manufacturing method thereof. The support structure provides the chip-redistribution encapsulant with a uniform support to avoid the chip being fragmentized due to uneven stress during the grinding process, so that the package, conformed to the trend of thinned thickness, is prevented from external damage and the conformity rate of the package is increased.

According to a first aspect of the present invention, a method for manufacturing a semiconductor package is provided. The manufacturing method includes the following steps: A carrier having an adhesion layer is provided. A plurality of chips are disposed on the adhesion layer, wherein an active surface of each chip faces the adhesion layer. A molding compound is formed for encapsulating the chips to form a chip-redistribution encapsulant having a first surface and a second surface opposite to the first surface, wherein the first surface has a chip area and a peripheral area. The carrier and the adhesion layer are removed, so that the chip-redistribution encapsulant exposes the active surface of each chip. A plurality of solder balls are uniformly formed in the chip area and the peripheral area. The second surface of the chip-redistribution encapsulant is grinded to reduce the thickness of the chip-redistribution encapsulant, wherein the solder balls provide the chip-redistribution encapsulant with a uniform support. The chip-redistribution encapsulant is sawn to form a plurality of packages.

According to a second aspect of the present invention, a method for manufacturing a semiconductor package is provided. The manufacturing method includes the following steps: A carrier having an adhesion layer is provided. At least one alignment marking element is disposed on the adhesion layer, and a plurality of chips are disposed on the adhesion layer according to the alignment marking element, wherein each chip has an active surface facing the adhesion layer and includes a plurality of pads on the active surface. A molding compound is formed for encapsulating the chips and the alignment marking element to form a chip-redistribution encapsulant, wherein the chip-redistribution encapsulant includes a first surface and a second surface opposite to the first surface, the first surface includes a chip area and a peripheral area which surrounds the chip area, and the chips and the alignment marking element are located in the chip area. The carrier and the adhesion layer are removed, so that the chip-redistribution encapsulant exposes the active surface and the alignment marking element of each chip. A plurality of signal I/O solder balls are disposed on the first surface of the chip-redistribution encapsulant. A plurality of support balls are disposed under the alignment marking element and are in the peripheral area. The chip-redistribution encapsulant is grinded to reduce the thickness of the chip-redistribution encapsulant, wherein the solder balls provide the chip-redistribution encapsulant with a uniform support. The chip-redistribution encapsulant is sawn to form a plurality of packages.

According to a third aspect of the present invention, a semiconductor package is provided. The semiconductor package includes a plurality of chips, a molding compound, and a plurality of solder balls. Each chip has an active surface and includes a plurality of pads on the active surface. The molding compound encapsulates the chips to form a chip-redistribution encapsulant. The chip-redistribution encapsulant includes a first surface and a second surface opposite to the first surface. The first surface includes a chip area and a peripheral area which surrounds the chip area. A plurality of solder balls are disposed in the chip area and the peripheral area which are located on the first surface of the chip-redistribution encapsulant for providing the chip-redistribution encapsulant with a uniform support.

The invention will become apparent from the following detailed description of the preferred but non-limiting embodiments. The following description is made with reference to the accompanying drawings.

### BRIEF DESCRIPTION OF THE DRAWINGS

FIG. 1 (Prior Art) shows fragmentation occurring to the chip-redistribution encapsulant;

FIG. 2A (Prior Art) shows a chip-redistribution encapsulant receiving stress during the grinding process;

FIG. 2B shows a chip-redistribution encapsulant receiving stress during the grinding process according to a preferred embodiment of the invention;

FIG. 3 shows a flowchart of a method of manufacturing a semiconductor package according to a preferred embodiment of the invention;

FIGS. 4A-4G show procedures of a method of manufacturing a semiconductor package according to a preferred embodiment of the invention;

FIG. 5 shows a semiconductor package according to a preferred embodiment of the invention;

FIG. 6 shows a chip area support structure according to a preferred embodiment of the invention; and

FIG. 7 shows a peripheral area support structure according to a preferred embodiment of the invention.

### DETAILED DESCRIPTION OF THE INVENTION

The invention mainly provides a semiconductor package and a manufacturing method thereof. The chip-redistribution encapsulant has a support structure which provides the chip-redistribution encapsulant with a uniform support in the backside grinding process. In the following embodiments, the support structure is disposed in the peripheral area of the chip-redistribution encapsulant or under the alignment marking element, so that the entire chip-redistribution encapsulant substantially has the same thickness and strength.

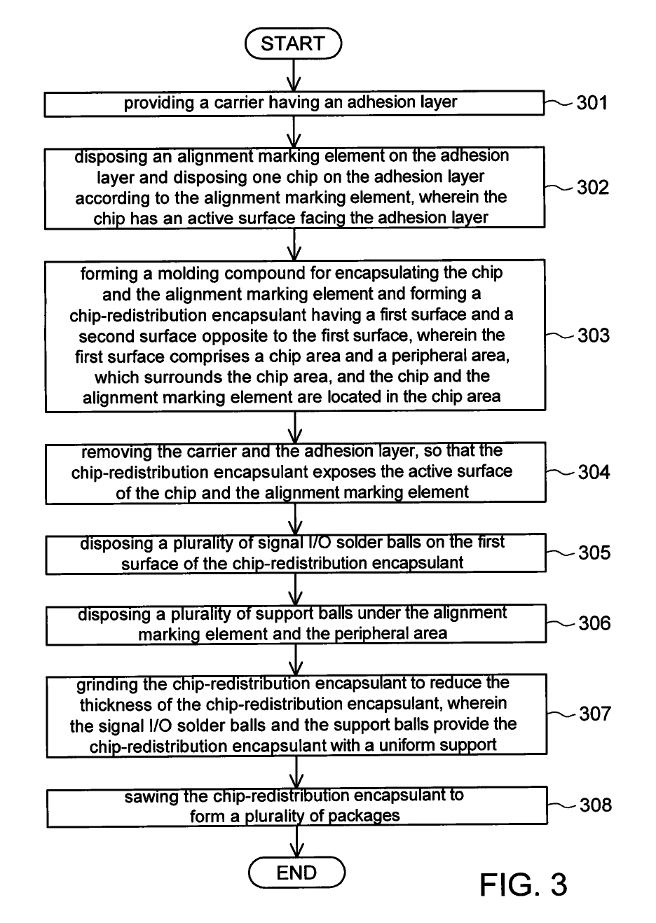

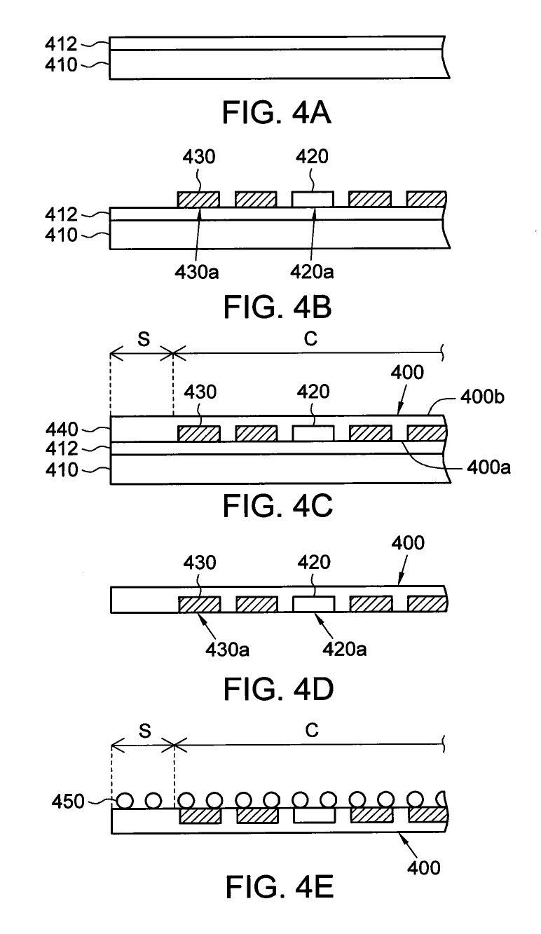

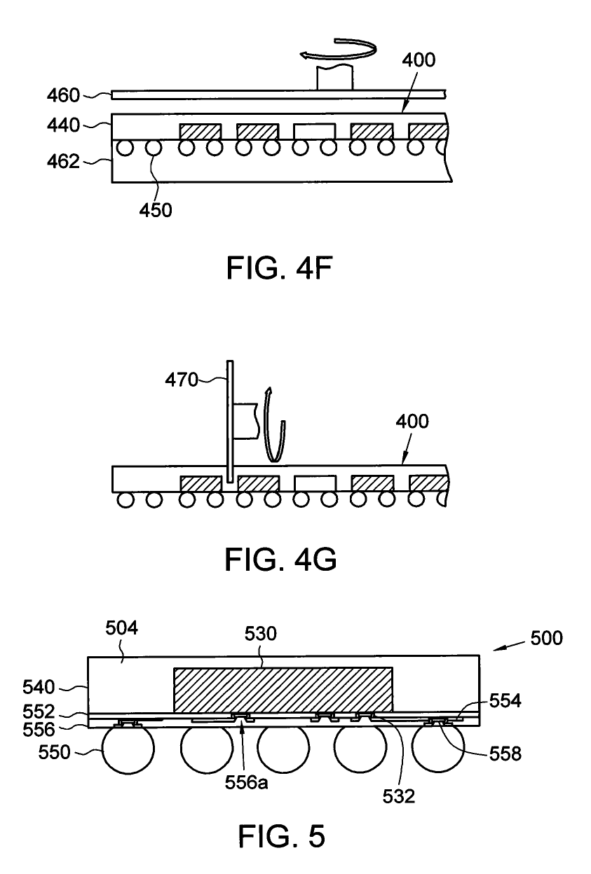

Referring to FIG. 3, a flowchart of a method of manufacturing a semiconductor package according to a preferred embodiment of the invention is shown. FIGS. 4A˜4G show procedures of a method of manufacturing a semiconductor package according to a preferred embodiment of the invention.

Firstly, in step 301 of FIG. 3 and FIG. 4A, a carrier 410 having an adhesion layer 412 is provided, wherein both surfaces of the adhesion layer 412 possess adhesion and one surface is adhered on the carrier 410.

Next, in step 302 of FIG. 3 and FIG. 4B, at least one alignment marking element 420 is disposed on the adhesion layer 412, and a plurality of chips 430 are disposed on the adhesion layer 412 according to the alignment marking element 420, so that each chip 430 can be precisely positioned. As the other surface of the adhesion layer 412 also possesses adhesion, the surface 420a of the alignment marking element 420 and the active surface of chip 430 face the adhesion layer 512 and are directly adhered on the other surface of the adhesion layer 412. Preferably, the alignment marking element 420 is a dummy chip.

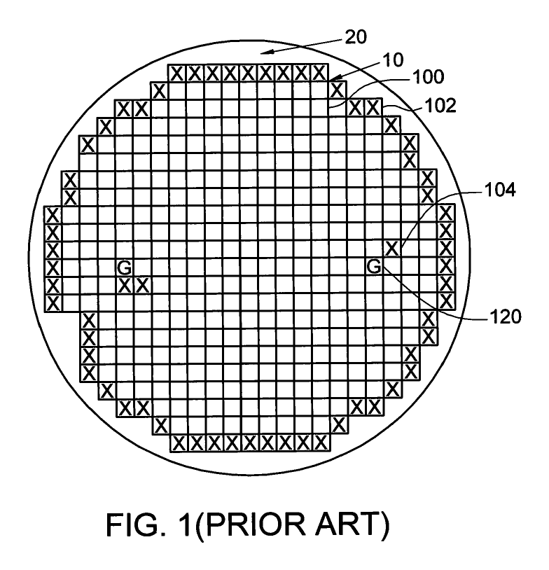

As indicated in step 303 of FIG. 3 and FIG. 4C, a molding compound 440 is formed on the adhesion layer 412 for encapsulating the chips 430 and the alignment marking element 420 to form a chip-redistribution encapsulant 400, wherein the chip-redistribution encapsulant 400 includes a first surface 400a and a second surface 400b opposite to the first surface 400a, and the first surface 400a includes a chip area C and a peripheral area S, which surrounds the chip area C, and the chips 430 and the alignment marking element 420 are located in the chip area C. The shape of the chip-redistribution encapsulant 400 can be a circle, an ellipse, a square, a rectangle, or other shapes as indicated in FIG. 1. The molding compound 440 is formed by way of dispensing a molding compound material and further heating the molding compound material to be solidified as a molding compound.

Moreover, in step 304 of FIG. 3 and FIG. 4D, the carrier 410 and the adhesion layer 412 (illustrated in FIG. 4C) are sequentially removed from the first side (that is, the chip-redistribution encapsulant surface) of the chip-redistribution encapsulant 400, so that the first side of the chip-redistribution encapsulant 400 exposes the active surface 430a of the chips 430 as well as the surface 420a of the alignment marking element 420.

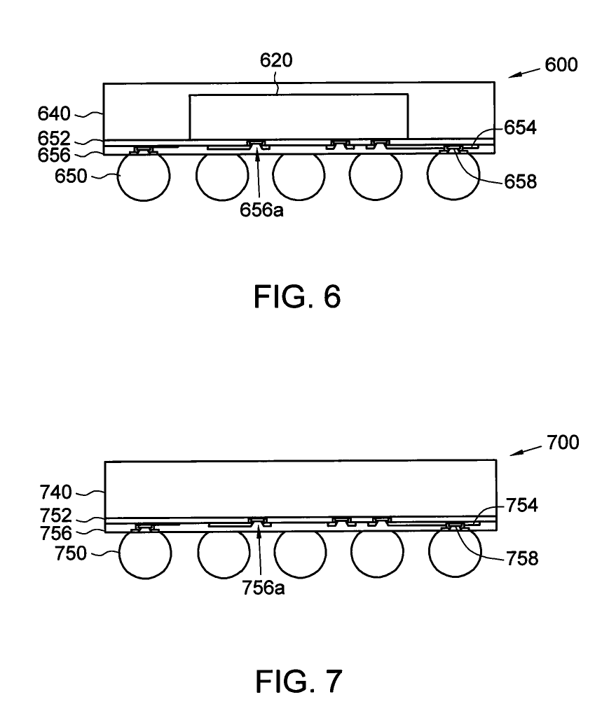

Next, as indicated in FIG. 4E, the entire chip-redistribution encapsulant 400 is turned upside down, so that a plurality of solder balls 450 are uniformly formed in the chip area C and the peripheral area S from the first side of the chip-redistribution encapsulant 400 in step 305 of FIG. 3. As indicated in FIG. 4E, the solder balls 450 are preferably formed in the chip area C and the peripheral area S at an equal distance. FIGS. 5, 6 and 7 respectively show a semiconductor package 500, a chip area support structure 600 and a peripheral area support structure 700 according to a preferred embodiment of the invention. The solder balls of the preferred embodiment of the invention include a plurality of signal I/O solder balls 550 and a plurality of support balls 650, 750. The step of forming the solder balls can be further divided into the following sub-steps. As indicated in FIGS. 5, 6 and 7, a plurality of pads 532 are disposed on the active surface of the chip 530, and the first dielectric layer 552, 652 are formed in the chip area C, and the first dielectric layer 752 is formed in the peripheral area S, and the pads 532 are exposed from the first dielectric layer 552. Next, the re-distribution layers 554 and 654 are formed on the first dielectric layers 552 and 652 in the chip area C and the re-distribution layer 754 is formed on the first dielectric layer 752 in the peripheral area S. Moreover, a plurality of solder pads 558 and 658 are formed on the re-distribution layers 554 and 654 in the chip area C, and a plurality of solder pads 758 are formed on the re-distribution layer 754 in the peripheral area S. Thereafter, the second dielectric layers 556 and 656 are formed in the chip area C, the second dielectric layer 756 is formed in the peripheral area S, and the solder pads 558, 658, 758 are respectively exposed from the openings 556a, 656a and 756a of the second dielectric layers 556, 656 and 756. Moreover, a plurality of signal I/O solder balls 550 are disposed on the solder pads 558, and a plurality of support balls are disposed on the solder pads 658 and 758, so that the solder balls 550, 650 and 750 respectively are located under the chip 530, the alignment marking element 620 and the molding compound 740 in the peripheral area S. The height of the solder balls is exemplified as 240 μm, and the thickness of the second dielectric layer is exemplified as 6 μm.

Besides, as indicated in FIG. 4F, the entire chip-redistribution encapsulant 400 is again turned upside down, and prior to the grinding process, a film of grinding tape 462 is adhered on the first side of the chip-redistribution encapsulant 400 to avoid the surface of the chip-redistribution encapsulant directly receiving a stress which may damage the solder balls 450 during the grinding process. The grinding tape 462 is preferably a UV tape. In step 306 of FIG. 3, the molding compound 440 is grinded from the second side (that is, the back of the chip-redistribution encapsulant) of the chip-redistribution encapsulant 400 to reduce the thickness of the chip-redistribution encapsulant 400, wherein the solder balls 450 provides the chip-redistribution encapsulant 400 with a uniform support.

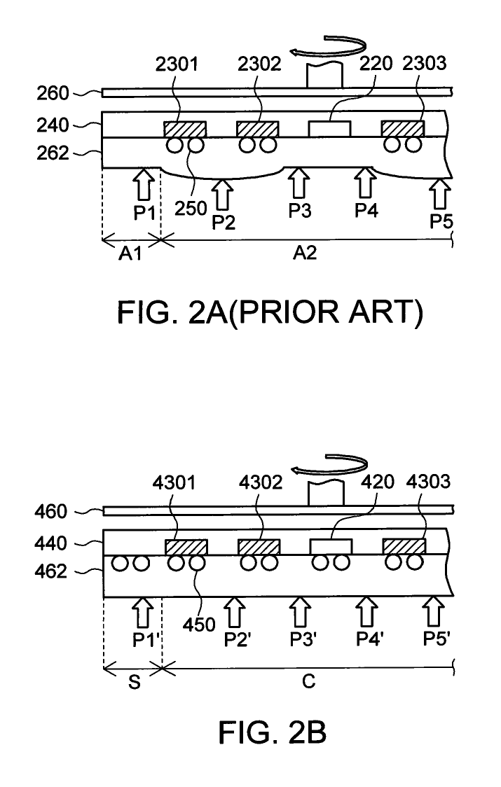

Referring to FIG. 2B, a chip-redistribution encapsulant receiving stress during the grinding process according to a preferred embodiment of the invention is shown. When the grinding tool 460 grinds the molding compound 440 from the back of the chip-redistribution encapsulant, the solder balls 450, which are already formed on the chips 4301, 4302 and 4303 in step 306 and further formed in the peripheral area S of the chip-redistribution encapsulant and under the alignment marking element 420, are respectively used as a support structure for the peripheral area and a support structure for the chip area, so that the entire chip-redistribution encapsulant can have uniformed stress. As indicated in FIG. 2B, on the part of the chip-redistribution encapsulant, the stress P1′ received in the peripheral area S, the stresses P3′ and P4′ received directly under the alignment marking element 420 in the chip area C and the stresses P2′ and P5′ received in other part of the chip-redistribution encapsulant are all the same. Thus, the stresses received on the two sides of each of the chips 4301, 4302, 4303 are consistent (P1=P2′; P3′>P2′ and P4′>P5′), effectively avoiding fragmentation occurring to the part of the chip 4301 near the peripheral area S or the part of the chips 4302 and 4303 near the alignment marking element 420 due to the received stress being uneven.

Following the grinding process but prior to the step of sawing the chip-redistribution encapsulant, the grinding tape 462 is removed. Lastly, in step 307 of FIG. 3 and FIG. 4G, according to the position of the chips 430, the chip-redistribution encapsulant 400 is sawn by the sawing tool 470 to form a plurality of packages, and the method of manufacturing a semiconductor package according to a preferred embodiment of the invention is completed here. The semiconductor package of the invention is preferably a fan-out package structure. As indicated in FIG. 5, the fan-out package structure includes a fan-out portion 504 which surrounds the chip 530, wherein, the first dielectric layer 552, the re-distribution layer 554, the second dielectric layer 556, solder pads 558 and solder balls 550 are further extended and disposed on the fan-out portion 554, so that more signal I/O solder balls 550 are uniformly distributed on the package 500 and the contact points are expanded.

According to the semiconductor package and the manufacturing method thereof disclosed in the above embodiments of the invention, a support structure is disposed in the peripheral area of the chip-redistribution encapsulant and under the alignment marking element for providing the chip-redistribution encapsulant with a uniform support. Thus, the entire chip-redistribution encapsulant substantially has consistent thickness and strength during the backside grinding process, hence avoiding the chip being fragmentized due to uneven stress during the grinding process, so that the package, conformed to the trend of thinned thickness, is prevented from external damage, the conformity rate of the package is increased, and labor cost is saved.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a semiconductor package, wherein the method comprises the following steps:
providing a carrier having an adhesion layer;
disposing a plurality of chips on the adhesion layer, wherein each chip has an active surface facing the adhesion layer and comprises a plurality of pads on the active surface;
forming a molding compound for encapsulating the chips to form a chip-redistribution encapsulant, wherein the chip-redistribution encapsulant comprises a first surface and a second surface opposite to the first surface, the first surface comprises a chip area and a peripheral area which surrounds the chip area;
removing the carrier and the adhesion layer, so that the chip-redistribution encapsulant exposes the active surface of the chip;
forming a plurality of solder balls in the chip area and the peripheral area which are located on the first surface of the chip-redistribution encapsulant;
grinding the second surface of the chip-redistribution encapsulant to reduce the thickness of the chip-redistribution encapsulant, wherein the solder balls provide the chip-redistribution encapsulant with a uniform support; and
sawing the chip-redistribution encapsulant to form a plurality of packages.

2. The manufacturing method according to claim 1, wherein prior to the step of disposing a plurality of chips on the adhesion layer, the method further comprises:
disposing at least one alignment marking element on the adhesion layer and disposing a plurality of chips on the adhesion layer according to the alignment marking element.

3. The manufacturing method according to claim 2, wherein the solder balls comprise a plurality of signal I/O solder balls and a plurality of support balls, and the step of forming the solder balls comprises:
disposing the signal I/O solder balls on the active surface of each chip; and
disposing the support balls on the surface of the alignment marking element.

4. The manufacturing method according to claim 1, wherein the solder balls comprise a plurality of signal I/O solder balls and a plurality of support balls, and the step of forming the solder balls comprises:
disposing the signal I/O solder balls on the active surface of each chip; and
disposing the support balls in the peripheral area of the chip-redistribution encapsulant.

5. The manufacturing method according to claim 1, wherein the step of forming the solder balls comprises:
forming a first dielectric layer in the chip area and the peripheral area;
forming a re-distribution layer in the chip area and the peripheral area;
forming a plurality of solder pads on the re-distribution layer; and
disposing the solder balls on the solder pads.

6. The manufacturing method according to claim 5, wherein the step of forming the solder balls further comprises:
forming a second dielectric layer on the re-distribution layer; and
forming a plurality of openings on the second dielectric layer for exposing the solder pads of the re-distribution layer.

7. The manufacturing method according to claim 2, wherein prior to the step of forming the solder balls, the method further comprises:
forming a first dielectric layer on the chip, the alignment marking element and the peripheral area;
forming a re-distribution layer on the chip, the alignment marking element and the peripheral area;
forming a plurality of solder pads on the re-distribution layer; and
disposing the solder balls on the solder pads.

8. The manufacturing method according to claim 7, wherein the step of forming the solder balls further comprises:
forming a second dielectric layer on the re-distribution layer; and
forming a plurality of openings on the second dielectric layer for exposing the solder pads of the re-distribution layer.

9. The manufacturing method according to claim 1, wherein prior to the step of grinding the chip-redistribution encapsulant, the manufacturing method further comprises:
adhering a UV tape on the first surface of the chip-redistribution encapsulant; and
removing the UV tape prior to the step of sawing the chip-redistribution encapsulant.

10. A method for manufacturing a semiconductor package, wherein the method comprises the following steps:
providing a carrier having an adhesion layer;
disposing at least one alignment marking element on the adhesion layer and disposing at least one chip on the adhesion layer according to the alignment marking element, wherein the chip has an active surface facing the adhesion layer and comprises a plurality of pads on the active surface;
forming a molding compound for encapsulating the chip and the alignment marking element and forming a chip-redistribution encapsulant, wherein the chip-redistribution encapsulant comprises a first surface and a second surface opposite to the first surface comprising a chip area and a peripheral area, which surrounds the chip area, and the chip and the alignment marking element are located in the chip area;
removing the carrier and the adhesion layer, so that the chip-redistribution encapsulant exposes the active surface of the chip and the alignment marking element;
disposing a plurality of signal I/O solder balls on the first surface of the chip-redistribution encapsulant;
disposing a plurality of support balls under the alignment marking element and the peripheral area;
grinding the chip-redistribution encapsulant to reduce the thickness of the chip-redistribution encapsulant, wherein the signal I/O solder balls and the support balls provide the chip-redistribution encapsulant with a uniform support; and
sawing the chip-redistribution encapsulant to form a plurality of packages.

11. The manufacturing method according to claim 10, wherein the method further comprises:
forming a first dielectric layer in the chip area and the peripheral area;
forming a re-distribution layer in the chip area and the peripheral area; and
forming a plurality of solder pads on the re-distribution layer, wherein the signal I/O solder balls and the support balls are formed on the solder pads.

12. The manufacturing method according to claim 11, wherein following the step of forming the solder pads, the method further comprises:
forming a second dielectric layer on the re-distribution layer; and
forming a plurality of openings on the second dielectric layer for exposing the solder pads of the re-distribution layer.

13. The manufacturing method according to claim 10, wherein following the step of forming the solder pads, the method further comprises:
forming a second dielectric layer on the re-distribution layer disposed in the chip area and the peripheral area; and
forming a plurality of openings on the second dielectric layer for exposing the solder pads of the re-distribution layer.

14. A semiconductor package, comprising:
a plurality of chips, wherein each chip has an active surface and comprises a plurality of pads on the active surface;
a molding compound for encapsulating the chips to form a chip-redistribution encapsulant, wherein the chip-redistribution encapsulant comprises a first surface and a second surface opposite to the first surface, and the first surface comprises a chip area and a peripheral area, which surrounds the chip area; and
a plurality of solder balls disposed in the chip area and the peripheral area on the first surface of the chip-redistribution encapsulant for providing the chip-redistribution encapsulant with a uniform support.

15. The package according to claim 14, wherein the solder balls comprises:
a plurality of signal I/O solder balls disposed on the active surface of the chips; and
a plurality of support balls disposed on the first surface located in the peripheral area.

16. The package according to claim 14, wherein the package further comprises:
at least one alignment marking element disposed between the chips, wherein an interval between the alignment marking element and its adjacent chip is equal to an interval between two neighboring chips.

17. The package according to claim 16, wherein the solder balls comprise:
a plurality of signal I/O solder balls disposed on the active surface of the chips; and
a plurality of support balls disposed on the first surface in the peripheral area and on the surface of the alignment marking element.

18. The package according to claim 14, wherein the package further comprises:
a first dielectric layer disposed on the first surface in the chip area and the peripheral area, and the first dielectric layer has a plurality of openings for exposing the pads;
a re-distribution layer disposed on the first dielectric layer, the exposed pads and the side-wall of the openings; and
a second dielectric layer disposed on the re-distribution layer and the first dielectric layer.

19. The package according to claim 14, wherein the package further comprises:
a first dielectric layer disposed on the active surface, the surface of the alignment marking element and the first surface of the peripheral area, and the first dielectric layer has a plurality of openings for exposing the pads;
a re-distribution layer disposed on the first dielectric layer, the exposed pads and the side-wall of the openings; and
a second dielectric layer disposed on the re-distribution layer and the first dielectric layer.

20. The package according to claim 14, wherein the second dielectric layer has a plurality of openings for exposing the re-distribution layer, and the package further comprises:
a plurality of solder pads disposed on the re-distribution layer, wherein the solder balls are disposed on the solder pads.
